(19) United States
(12) Patent Application Publication
(10) Pub. No.: US 2026/0140164 A1
(43) Pub. Date: May 21, 2026

(54) DYNAMIC SELECTION OF OPERATIONS FOR A SELF-TEST OF AN INTEGRATED CIRCUIT

(71) Applicant: QUALCOMM Incorporated, San Diego, CA (US)

(72) Inventors: Pravinkumar Nagjibhai Gondaliya, Bangalore (IN); Devadatta Bhat, Bangalore (IN); Sanjay Krishna Hulical Vijayaraghavachar, Bangalore (IN); Mithun Puthiyonnan, Bangalore (IN)

(21) Appl. No.: 18/955,644

(22) Filed: Nov. 21, 2024

(51) Int. Cl. G01R 31/28

(52) U.S. Cl. CPC G01R 31/2856; G01R 31/287; G01R 31/2879

(57) ABSTRACT

An apparatus for a self-test of an integrated circuit includes a processing system including one or more processors and one or more memories coupled to the one or more processors. The processing system is configured to receive control information associated with the integrated circuit. The control information indicates one or more of a power usage associated with the integrated circuit or an idle period associated with the integrated circuit. The processing system is further configured to initiate, based on a trigger event associated with the self-test of the integrated circuit, one or more operations of the self-test. The one or more operations are selected in accordance with one or more criteria from among a plurality of operations scheduled to be performed in connection with the self-test. The one or more operations are to be performed during the idle period.

### TECHNICAL FIELD

Aspects of the present disclosure relate generally to integrated circuits, and more particularly, to self-tests of integrated circuits.

### DESCRIPTION OF THE RELATED TECHNOLOGY

Electronic devices increasingly perform a variety of functions for users. For example, in addition to supporting voice calls, a mobile device (such as a smart phone) may support a variety of other operations and may include a variety of electronic components to support these operations. As another example, a vehicle may support wireless communications, navigation, and other driver assistance features such as adaptive cruise control, lane change assistance, collision avoidance, night vision, parking assistance, blind spot detection, lane keeping assistance, automated braking, partially autonomous driving, and fully autonomous driving.

To enable these and other features, devices may include one or more integrated circuits. One example of an integrated circuit is a system-on-chip (SoC). SoCs and other integrated circuits are typically subject to a variety of tests during design, production, and end use phases. Such testing may involve relatively sophisticated circuitry and testing processes, which may increase cost of the integrated circuits as well as the devices that include such integrated circuits.

One example of such a test is a built-in self-test (BIST). An integrated circuit may perform a BIST to internally check functionality and to detect potential faults or failures. Some BISTs may be performed without external testing equipment. Performing a BIST can consume resources (such as processing resources and power), which can reduce performance of a device, operating life of a device, or both.

### SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

In some aspects, an apparatus for a self-test of an integrated circuit includes a processing system including one or more processors and one or more memories coupled to the one or more processors. The processing system is configured to receive control information associated with the integrated circuit. The control information indicates one or more of a power usage associated with the integrated circuit or an idle period associated with the integrated circuit. The processing system is further configured to initiate, based on a trigger event associated with the self-test of the integrated circuit, one or more operations of the self-test. The one or more operations are selected in accordance with one or more criteria from among a plurality of operations scheduled to be performed in connection with the self-test. The one or more operations are to be performed during the idle period.

In some additional aspects, a method of operation of a test controller of an integrated circuit includes receiving control information associated with the integrated circuit. The control information indicates one or more of a power usage associated with the integrated circuit or an idle period associated with the integrated circuit. The method further includes initiating, based on a trigger event associated with a self-test of the integrated circuit, one or more operations of the self-test. The one or more operations are selected in accordance with one or more criteria from among a plurality of operations scheduled to be performed in connection with the self-test. The one or more operations are to be performed during the idle period.

In some further aspects, a non-transitory computer-readable medium stores instructions executable by one or more processors to initiate, perform, or control operations of a self-test of an integrated circuit. The operations include receiving control information associated with the integrated circuit. The control information indicates one or more of a power usage associated with the integrated circuit or an idle period associated with the integrated circuit. The operations further include initiating, based on a trigger event associated with the self-test of the integrated circuit, one or more operations of the self-test. The one or more operations are selected in accordance with one or more criteria from among a plurality of operations scheduled to be performed in connection with the self-test. The one or more operations to be performed during the idle period.

While aspects and implementations are described in this application by illustration to some examples, those skilled in the art will understand that additional implementations and use cases may come about in many different arrangements and scenarios. Innovations described herein may be implemented across many differing platform types, devices, systems, shapes, sizes, and packaging arrangements. For example, aspects and/or uses may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described aspects. It is intended that innovations described herein may be practiced in a wide variety of devices, chip-level components, systems, distributed arrangements, end-user devices, etc. of varying sizes, shapes, and constitution.

To the accomplishment of the foregoing and related ends, the one or more aspects include the features hereinafter described and pointed out in the claims. The following description and the drawings set forth in detail certain illustrative features of the one or more aspects. These features are indicative, however, of but a few of the various ways in which the principles of various aspects may be employed.

### BRIEF DESCRIPTION OF THE DRAWINGS

FIG. 1 is a block diagram illustrating an example of a system-on-chip (SoC) that supports dynamic selection of operations for a self-test.

FIG. 2 is a block diagram illustrating examples of a vehicle and a mobile device that support dynamic selection of operations for a self-test.

FIG. 3 is a block diagram illustrating examples of features that may be associated with a dynamic self-test scheduler supporting dynamic selection of operations for a self-test.

FIG. 4 is a block diagram illustrating additional examples of features that may be associated with the dynamic self-test scheduler supporting dynamic selection of operations for a self-test.

FIG. 5 is a block diagram illustrating additional examples of features that may be associated with the dynamic self-test scheduler supporting dynamic selection of operations for a self-test.

FIG. 6 is a flow chart illustrating an example of a method that supports dynamic selection of operations for a self-test.

Like reference numbers and designations in the various drawings indicate like elements.

### DETAILED DESCRIPTION

The detailed description set forth below in connection with the drawings describes various configurations and does not represent the only configurations in which the concepts described herein may be practiced. The detailed description includes specific details for the purpose of providing a thorough understanding of various concepts. However, these concepts may be practiced without these specific details. In some instances, well known structures and components are shown in block diagram form in order to avoid obscuring such concepts.

Various aspects relate generally to dynamic selection of operations for a self-test of an integrated circuit. In some aspects, operations are selected for the self-test based on one or more criteria that may dynamically change during operation of the integrated circuit. For example, the one or more criteria may include one or more of a power metric (e.g., an amount of power that is available during an idle period associated with the integrated circuit) or a time metric (e.g., a duration of the idle period). In such examples, a group of operations may be selected that satisfy the one or more criteria (e.g., without exceeding the power metric or the time metric). The group of operations may correspond to a subset of a larger group of operations that are periodically performed in connection with the self-test.

Particular aspects of the subject matter described in this disclosure can be implemented to realize one or more of the following potential advantages. In some examples, by dynamically selecting operations for a self-test based on one or more of a power metric or a time metric, operation may be improved as compared to some other testing techniques. To illustrate, some conventional testing techniques may involve periodically performing operations based on a least-recently used (LRU) technique irrespectively of one or more of a power consumption associated with the operations or a time duration associated with the operations. As a result, in some conventional techniques, a test may cause a power reduction event (e.g., where an amount of power available is insufficient to perform one or more operations due to power consumption associated with the test), a stall condition (e.g., where a processor is unable to execute instructions, access a memory, or perform other operations due to resources being utilized in connection with the test), or a malfunction in case of the power consumption exceeding a power budget. Accordingly, by dynamically selecting operations for a self-test based on one or more of a power metric or a time metric, operation may be improved (e.g., by avoiding one or more of a power reduction event or a stall condition).

Several aspects are presented with reference to various apparatus and methods. These apparatus and methods are described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. When multiple processors are implemented, the multiple processors may perform the functions individually or in combination. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software, whether referred to as software, firmware, middleware, microcode, hardware description language, or otherwise, shall be construed broadly to mean instructions, instruction sets, code, code segments, program code, programs, subprograms, software components, applications, software applications, software packages, routines, subroutines, objects, executables, threads of execution, procedures, functions, or any combination thereof. One or more processors in the processing system may execute software to cause a device that includes the one or more processors to perform the various functionality described throughout this disclosure.

Accordingly, in one or more example aspects, implementations, and/or use cases, the functions described may be implemented in hardware, software, or any combination thereof. If implemented in software, the functions may be stored on or encoded as one or more instructions or code on a computer-readable medium. Computer-readable media include computer storage media. Storage media may be any available media that can be accessed by a computer. By way of example, such computer-readable media can include a random-access memory (RAM), a read-only memory (ROM), an electrically erasable programmable ROM (EEPROM), optical disk storage, magnetic disk storage, other magnetic storage devices, combinations of the types of computer-readable media, or any other medium that can be used to store computer executable code in the form of instructions or data structures that can be accessed by a computer (e.g., transitory or non-transitory medium that may be accessed by computer).

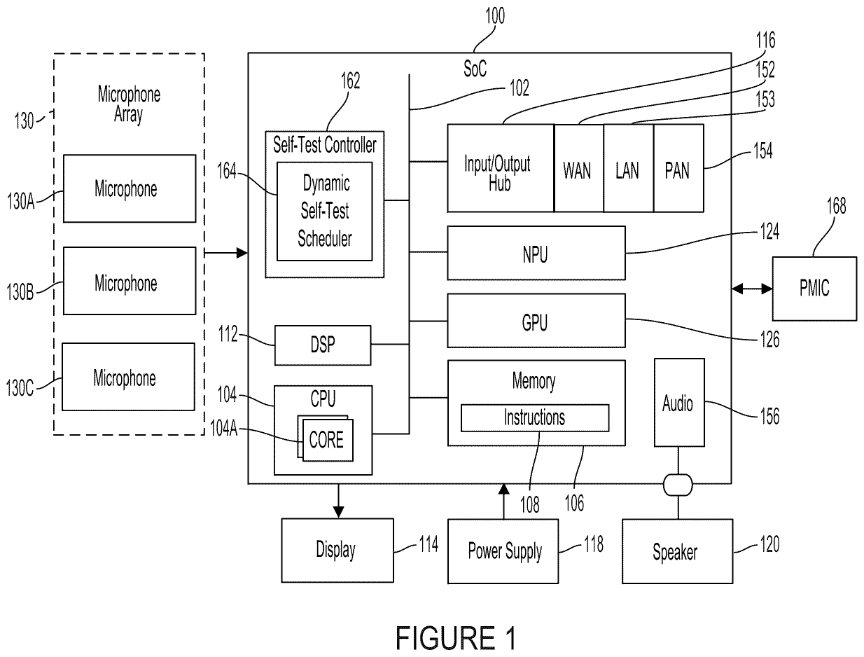

FIG. 1 is a block diagram illustrating an example of a system-on-chip (SoC) 100 that supports dynamic selection of operations for a self-test. The SoC 100 may include several components coupled together through a bus 102, which may be a network-on-a-chip (NoC) or a plurality of NOCs interconnecting various components. For example, although FIG. 1 illustrates several components coupled to the bus 102, the several components may be coupled to different busses with additional busses connecting the different busses to provide a path for communication between the components.

One example component in the SoC 100 is a digital signal processor (DSP) 112 for signal processing. The DSP 112 may process audio signals received from microphones 130A, 130B, and 130C of microphone array 130. The DSP 112 may include hardware customized for performing a limited set of operations on specific kinds of data. For example, a DSP may include transistors coupled together to perform operations on streaming data and use memory architectures and/or access techniques to fetch multiple data or instructions concurrently. Such configurations may allow the DSP 112 to operate on real-time data, such as video data, audio data, or modem data, in a power-efficient manner.

The SoC 100 also includes a central processing unit (CPU) 104 and a memory 106 storing instructions 108 (e.g., a memory storing processor-readable code or a non-transitory computer-readable medium storing instructions) that may be executed by a processor of the SoC 100. The CPU 104 may be a single central processing unit (CPU) or a CPU cluster comprising two or more cores such as core 104A. The CPU 104 may include hardware capable of performing generic operations on many kinds of data, such as hardware capable of executing instructions from the Advanced RISC Machines (ARM®) instruction set, such as ARMv8 and ARMv9. For example, a CPU 104 may include transistors coupled together to perform operations for supporting executing an operating system and user applications (e.g., a camera application, a multimedia application, a gaming application, a productivity application, a messaging application, a videocall application, an audio recording application, a video recording application). The CPU 104 may execute instructions 108 retrieved from the memory 106. In some embodiments, the CPU 104 executing an operating system may coordinate execution of instructions by various components within the SoC 100. For example, the CPU 104 may retrieve instructions 108 from memory 106 and execute the instructions on the DSP 112.

The SoC 100 may further include or may execute one or more artificial intelligence (AI) accelerators. To illustrate, the SoC 100 may include a neural processing unit (NPU) 124 for executing machine learning (ML) models relating to multimedia applications. The NPU 124 may include hardware configured to perform and accelerate convolution operations involved in executing machine learning algorithms. For example, the NPU 124 may improve performance when executing predictive models such as artificial neural networks (ANNs) (including multilayer feedforward neural networks (MLFFNN), the recurrent neural networks (RNN), and/or the radial basis functions (RBF)). The ANN executed by the NPU 124 may access predefined training weights stored in the memory 106 for performing operations on user data.

The SoC 100 may be coupled to a display 114 for interacting with a user. The SoC 100 may also include a graphics processing unit (GPU) 126 for rendering images on the display 114. In some embodiments, the CPU 104 may perform rendering to the display 114 without a GPU 126. In some embodiments, the GPU 126 may be configured to execute instructions for performing operations unrelated to rendering images, such as for processing large volumes of datasets in parallel.

Input/output components may be coupled to the SoC 100 through an input/output (I/O) hub 116. An example of a I/O hub 116 is an interconnect to a peripheral component interconnect express (PCIe) bus. Example components coupled to the I/O hub 116 may be components used for interacting with a user, such as a touch screen interface and/or physical buttons. Some components coupled to the I/O hub 116 may also include network interfaces for communicating with other devices, including a wide area network (WAN) adaptor (e.g., WAN adaptor 152), a local area network (LAN) adaptor (e.g., LAN adaptor 153), and/or a personal area network (PAN) adaptor (e.g., PAN adaptor 154). A WAN adaptor 152 may be a 4G LTE or a 5G NR wireless network adaptor. A LAN adaptor 153 may be an IEEE 802.11 WiFi wireless network adapter. A PAN adaptor 154 may be a Bluetooth wireless network adaptor. Each of the WAN adaptor 152, LAN adaptor 153, and/or PAN adaptor 154 may be coupled to an antenna that may be shared by each of the adaptors 152, 153, and 154, or coupled to multiple antennas configured for primary and diversity reception and/or configured for receiving specific frequency bands. In some embodiments, the WAN adaptor 152, LAN adaptor 153, and/or PAN adaptor 154 may share circuitry, such as portions of a radio frequency front end (RFFE).

Audio circuitry 156 may be integrated in SoC 100 as dedicated circuitry for coupling the SoC 100 to a speaker 120 external to the SoC 100, which may be a transducer such as a speaker (either internal to or external to a device incorporating the SoC 100) or headphones. The audio circuitry 156 may include coder/decoder (CODEC) functionality for processing digital audio signals. The audio circuitry 156 may further include one or more amplifiers (e.g., a class-D amplifier) for driving a transducer coupled to the SoC 100 for outputting sounds generated during execution of applications by the SoC 100. Functionality related to audio signals described herein may be performed by a combination of the audio circuitry 156 and/or other processors of the SoC (e.g., CPU 104, DSP 112, GPU 126, NPU 124).

The SoC 100 may couple to external devices outside the package of the SoC 100. For example, the SoC 100 may be coupled to a power supply 118, such as a battery or an adaptor to couple the SoC 100 to an energy source. The signal processing described herein may be adapted to and achieve power efficiency to support operation of the SoC 100 from a limited-capacity power supply 118 such as a battery. For example, operations may be performed on a portion of the SoC 100 configured for performing the operation at a lowest power consumption. As another example, operations themselves are performed in a manner that reduces an amount of computations to perform the operation, such that the algorithm is optimized for extending the operational time of a device while powered by a limited-capacity power supply 118. In some embodiments, the operations described herein may be configured based on a type of power supply 118 providing energy to the SoC 100. For example, a first set of operations may be executed to perform a function when the power supply 118 is a wall adaptor. As another example, a second set of operations may be executed to perform a function when the power supply 118 is a battery.

The SoC 100 may also include or be coupled to additional features or components that are not shown in FIG. 1. Although components are shown integrated as a single SoC 100, which may include all components built on a single semiconductor die with a common semiconductor substrate, other arrangements of the illustrated blocks different number of dies, substrates, and/or packages may be arranged to accomplish the same functionality described in this disclosure. Further, although some examples herein are described with reference to the SoC 100, it should be appreciated that the features described herein are also applicable to other types of integrated circuits.

The memory 106 may include a non-transient or non-transitory computer readable medium storing computer-executable instructions as instructions 108 to perform all or a portion of one or more operations described in this disclosure. The instructions 108 may include a multimedia application (or other suitable application such as a messaging application) to be executed by the SoC 100 that records, processes, or outputs audio signals. The instructions 108 may also include other applications or programs executed by the SoC 100, such as an operating system and applications other than for multimedia processing.

In addition to instructions 108, the memory 106 may also store audio data. The SoC 100 may be coupled to an external memory and configured to access the memory for writing output audio files for later playback or long-term storage. For example, the SoC 100 may be coupled to a flash storage device comprising NAND memory for storing video files (e.g., MP4-container formatted files) including audio tracks and/or storing audio recordings (e.g., MPEG-1 Layer 3 files, also referred to as MP3 files). Portions of the video or audio files may be transferred to memory 106 for processing by the SoC 100, with the resulting signals after processing encoded as video or audio files in the memory 106 for transfer to the long-term storage.

The SoC 100 may further include a self-test controller 162. The self-test controller 162 may be coupled (e.g., via the bus 102) to one or more components of the SoC 100, such as one or more of the CPU 104, the DSP 112, the I/O hub 116, the NPU 124, the GPU 126, or the memory 106. The self-test controller 162 may include or may execute a dynamic self-test scheduler 164. In some implementations, the dynamic self-test scheduler 164 may also be referred to as a “smart” logic built-in self-test (LBIST) scheduler.

In some examples, the SoC 100 may include or may be coupled to a power management component. For example, the SoC 100 may be coupled to a power management integrated circuit (PMIC) 168. In some implementations, the PMIC 168 may perform operations such as dynamically adjusting power consumption and voltage levels of at least some components of the SoC 100, performing thermal management associated with the SoC 100, and performing voltage regulation.

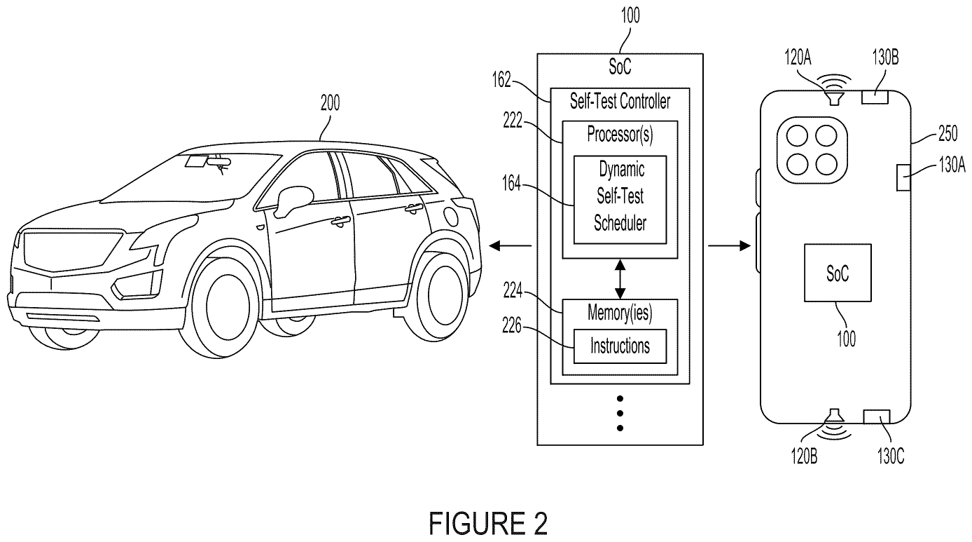

FIG. 2 is a block diagram illustrating examples of a vehicle 200 and a mobile device 250 that support dynamic selection of operations for a self-test. In some examples, the dynamic self-test scheduler 164 may perform dynamic scheduling of self-tests during operation of the vehicle 200 and the mobile device 250. As an illustrative example, the dynamic self-test scheduler 164 may schedule self-tests during driving of the vehicle 200. Further, although the example of FIG. 2 may illustrate a vehicle 200 and a mobile device 250, other examples are also within the scope of the disclosure. For example, in some implementations, the SoC 100 may be included in one or more other devices, such as another type of computing device (e.g., a desktop computer, a laptop computer, a tablet computer, or a server) or an Internet-of-Things (IoT) device, as illustrative examples.

The example of FIG. 2 also illustrates that the self-test controller 162 may include on or more processors 222. In some examples, one or more features of the dynamic self-test scheduler 164 may be implemented using the one or more processors 222. For example, the dynamic self-test scheduler 164 may be implemented using instructions executed by the one or more processors 222. Further, the self-test controller 162 may include, or may be coupled to, one or more memories 224. The one or more memories 224 may be coupled to the one or more processors 222. The one or more memories 224 may store instructions 226 executable by the one or more processors 222 to initiate, perform, or control one or more operations described herein.

In some examples, one or more of the vehicle 200 or the mobile device 250 may include or may be referred to as a user equipment (UE). Examples of UEs may include a cellular phone, a smart phone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs may be referred to as IoT devices (e.g., parking meter, gas pump, toaster, vehicles, heart monitor, etc.). A UE may also be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. In some scenarios, the term UE may also apply to one or more companion devices such as in a device constellation arrangement. One or more of these devices may collectively access the network and/or individually access the network.

In some examples, the vehicle 200 may operate using assisted driving and/or autonomous driving capabilities. Assisted driving, which may also be called advanced driver assistance systems (ADAS), may refer to a set of technologies designed to enhance vehicle safety and improve the driving experience by providing assistance and automation to the driver. These technologies may use various sensor(s), such as camera(s), radar(s), light detection and ranging (lidar(s) or lidar sensor(s)), etc., and other components to monitor a vehicle's surroundings and assist the driver of the vehicle 200 with certain driving tasks. For example, some features of assisted driving systems may include: (1) adaptive cruise control (ACC) (e.g., a system that automatically adjusts a vehicle's speed to maintain a safe following distance from the vehicle ahead), (2) lane-keeping assist (LKA) (e.g., a system that uses cameras to detect lane markings and helps keep the vehicle 200 centered within the lane, and provides steering inputs to prevent unintentional lane departure), (3), autonomous emergency braking (AEB) (e.g., a system that detects potential collisions with obstacles or pedestrians and automatically apply the brakes to avoid or mitigate the impact), (4) blind spot monitoring (BSM) (e.g., a system that uses sensors to detect vehicles in a driver's blind spots and provides visual or audible alerts to avoid potential collisions during lane changes), (5) parking assistance (e.g., a system that assists drivers in parking their vehicles by using camera(s) and sensor(s) to help with parallel parking or maneuvering into tight spaces), and/or traffic sign recognition (e.g., camera(s) and image processing are used to recognize and display traffic signs such as speed limits, stop signs, and other road regulations on the dashboard of the vehicle 200).

Autonomous driving, which may also be called as self-driving or driverless technology, may refer to the ability of the vehicle 200 to navigate and operate itself without specifying human intervention (e.g., travelling from one place to another place without a human controlling the vehicle). The goal of the autonomous driving is to create vehicles that are capable of perceiving their surroundings, making decisions, and controlling their movements, all without the direct involvement of a human driver. To achieve or improve the autonomous driving, the vehicle 200 may be specified to use a map (or map data) with detailed information, such as a high-definition (HD) map. An HD map may refer to a highly detailed and accurate digital map designed for use in autonomous driving and ADAS. In one example, HD maps may typically include one or more of: (1) geometric information (e.g., precise road geometry, including lane boundaries, curvature, slopes, and detailed 3D models of the surrounding environment), (2) lane-level information (e.g., information about individual lanes on the road, such as lane width, lane type (e.g., driving, turning, or parking lanes), and lane connectivity), (3) road attributes (e.g., data on road features like traffic signs, signals, traffic lights, speed limits, and road markings), (4) topology (e.g., information about the relationships between different roads, intersections, and connectivity patterns), (5) static objects (e.g., locations and details of fixed objects along the road, such as buildings, traffic barriers, and poles), (6) dynamic objects (e.g., real-time or frequently updated data about moving objects, like other vehicles, pedestrians, and cyclists), and/or (7) localization and positioning: precise reference points and landmarks that help in accurate vehicle localization on the map, etc.

Note while some assisted/autonomous driving systems may demand the use of HD map data, there are also assisted/autonomous driving systems and information systems that may be configured not to use HD map data (e.g., due to costs). For example, the Society of Automotive Engineers (SAE) has defined six levels of driving automation, from Level 0 (no automation) to Level 5 (full automation). For Level 0 (no automation), the human driver may be responsible for all aspects of driving, and the system may provide warnings or momentary assistance but does not take control of the vehicle 200. Example features for SAE Level 0 may include automatic emergency braking, blind spot warnings, and lane departure warnings, etc. As such, SAE Level 0 may not specify using HD map data. For Level 1 (driver assistance), the vehicle 200 may assist with either steering or acceleration/deceleration (but may not perform both simultaneously). The human driver is still responsible for most driving tasks and may need to be ready to take over at any time. Example features for SAE Level 1 may include adaptive cruise control or lane-keeping assistance (e.g., lane centering), etc. For Level 2 (partial automation), the vehicle 200 may control both steering and acceleration/deceleration under certain conditions, but the human driver is requested to remain engaged and monitor the driving environment at all times. Example features for SAE Level 2 may include ADAS, adaptive cruise control and lane-keeping assistance at the same time, etc. For Level 3 (conditional automation), the vehicle 200 may perform all driving tasks under specific conditions, and the human driver may not be specified to monitor the environment but may need to be ready to take over when requested by the system. Example features for SAE Level 3 may include traffic jam chauffeur, where the vehicle 200 is capable of handling driving in traffic jams without driver intervention. For Level 4 (high automation), the vehicle 200 is capable of handling all driving tasks within certain conditions or environments (geofenced areas). The system may operate without human intervention but may specify a human driver outside its operational domain. Example features for SAE Level 4 may include local driverless taxi and pedals/steering, etc. For Level 5 (full automation), the vehicle 200 is capable of performing all driving tasks under all conditions, and does not specify the human driver at any time. Example features for SAE Level 5 may include fully autonomous vehicles with no steering wheel or pedals. In summary, SAE Level 0 may be defined as features to provide warnings and assistance. ADAS is usually SAE Level 1 and 2, while AD is considered SAE level 3 to 5. Aspects presented herein (described below) may apply to all levels of SAE, including SAE Level 0 (e.g., for speed warning). For purposes of the present disclosure, a system or information system that is used in associated with SAE Level 0 to Level 5 may collectively be referred to as a “vehicle system,” which may encompass the assisted driving and the autonomous driving.

To enable assisted driving and/or autonomous driving, the vehicle 200 may be configured to use various machine learning (ML) and/or neural network (NN) frameworks. An ML/NN framework may refer to a set of tools, libraries, and/or software components that are configured to provide a structured way to design, build, and deploy ML/NN models and applications. These frameworks may be able to simplify the process of developing ML/NN algorithms and applications by providing a foundation of pre-built functions, algorithms, and utilities. They may typically include features for data preprocessing, model training, evaluation, and/or deployment, etc. ML/NN frameworks may come in various programming languages, and they may be configured to cater to different types of machine learning tasks, including supervised learning, unsupervised learning, and/or reinforcement learning, etc. An ML/NN model may refer to a mathematical representation of a real-world process or problem, created using ML/NN algorithms and techniques. These ML/NN models may be configured to make predictions, classify data, and/or solve specific tasks based on patterns and relationships learned from input data. A deep learning framework may refer to a specialized software library or toolset that provides specified components and abstractions for building, training, and deploying deep neural networks. Deep learning frameworks may be designed to facilitate the development of complex neural network models, especially deep neural networks with multiple layers. These frameworks may offer a wide range of pre-implemented layers, optimizers, loss functions, and other components, making it easier for researchers and developers to work with deep learning models.

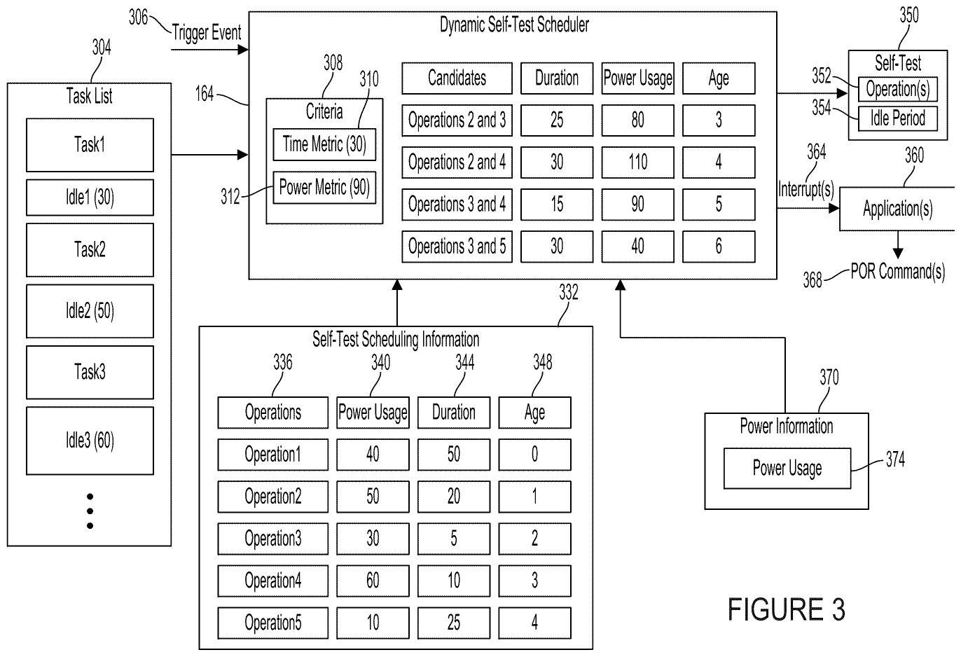

FIG. 3 is a block diagram illustrating examples of features that may be associated with the dynamic self-test scheduler 164 supporting dynamic selection of operations for a self-test. In the example of FIG. 3, the dynamic self-test scheduler 164 may initiate a self-test 350 of an integrated circuit (e.g., by outputting a self-test command that indicates the SoC 100 of FIGS. 1 and 2 is initiate the self-test 350). Examples of the self-test 350 may include a built-in self test (BIST), a logic BIST (LBIST), and a memory MBIST (MBIST). To further illustrate, the SoC 100 of FIGS. 1 and 2 may perform the self-test 350 to verify functionality of one or more components of the SoC 100 (e.g., one or more of the CPU 104, the DSP 112, the NPU 124, or the GPU 126) and to monitor for one or more conditions that may be associated with potential faults or failures of the one or more components.

In some examples, the dynamic self-test scheduler 164 may initiate the self-test 350 based on detecting a trigger event 306 associated with the self-test 350. In some examples, detecting the trigger event 306 may include detecting a bootup of the SoC 100. Alternatively, or in addition, detecting the trigger event 306 may include detecting expiration of a time interval since a prior iteration of the self-test 350.

The dynamic self-test scheduler 164 may receive self-test scheduling information 332 associated with the self-test 350. The self-test scheduling information 332 may indicate operations 336 scheduled to be performed in connection with the self-test 350 (e.g., operations performed periodically in connection with the self-test 350). For example, in some implementations, the operations 336 may include one or more of a combinational logic test operation, a sequential logic test operation, a pattern generation and response analysis operation, a fault coverage and defect detection operation, a boundary scan operation, a timing test operation, a functional test operation, a power test operation, a structural test operation, a reliability test operation, or one or more other test operations.

To further illustrate, operations 336 may include, for example, a first operation, a second operation, a third operation, a fourth operation, and a fifth operation (Operation1, Operation2, Operation3, Operation4, and Operation5, respectively). Each operation 336 may be associated with a respective power usage 340, a respective duration 344, and a respective age 348. To illustrate, the first operation (Operation1) may be associated with a power usage of 40, a duration of 50, and an age of 0. In some examples, the age 348 may be based on a least recently used (LRU) process associated with performance of the operations 336, such as where a more recently performed operation 336 may be associated with a greater age 348, and where a less recently performed operation 336 may be associated with a lower age 348.

The dynamic self-test scheduler 164 may select one or more operations 352 for the self-test 350 from among the operations 336, where the one or more operations 352 are to be performed during an idle period 354. In some aspects of the disclosure, the dynamic self-test scheduler 164 may dynamically select the one or more operations 352 based on one or more criteria 308. The one or more criteria 308 may include a time metric 310 associated with the idle period 354 (e.g., a duration of the idle period 354). Alternatively, or in addition, the one or more criteria 308 may include a power metric 312 associated with the idle period 354 (e.g., an amount of power that can be allocated to the one or more operations 352).

To illustrate, the dynamic self-test scheduler 164 may determine the time metric 310 in accordance with a task list 304. The task list 304 may indicate one or more tasks, such as a first task (Task1), a second task (Task2), and a third task (Task3). In some examples, the task list 304 may indicate tasks to be performed by one or more processors or other components of the SoC 100. For example, the task list 304 may indicate tasks to be performed by one or more of the CPU 104, the DSP 112, the NPU 124, or the GPU 126.

The dynamic self-test scheduler 164 may identify idle periods associated with the task list 304 and may select operations of the self-test 350 to be performed during the idle periods. The idle period 354 may correspond to such an idle period. To illustrate, a first idle period (Idle1) may occur between the first task and the second task, a second idle period (Idle2) may occur between the second task and the third task, and a third idle period (Idle3) may occur after the third task. In some examples, the idle period 354 may correspond to the first idle period (Idle1), the second idle period (Idle2), or the third idle period (Idle3)

In the example of FIG. 3, the first idle period may have a duration of 30 milliseconds (ms), the second idle period may have a duration of 50 ms, and the third idle period may have a duration of 60 ms. It is noted that such values are provided for illustration and that the disclosure is not limited to such values.

The dynamic self-test scheduler 164 may identify, based on the task list 304, that an idle period is to occur and may select operations of the self-test 350 to be performed during the idle periods. For example, the dynamic self-test scheduler 164 may identify, based on the task list 304, that the first idle period (Idle1) is to occur and that the first idle period is associated with a particular duration, such as 30 ms. In this example, the time metric 310 may correspond to 30 ms, and and the dynamic self-test scheduler 164 may select one or more operations 352 from among the operations 336 such that a duration of the one or more operations 352 is less than or equal to the time metric 310 (where the time metric 310 is based on, or corresponds to, the idle period 354).

To further illustrate, in the example of FIG. 3, Operation2 and Operation3 may have a combined duration of 25 ms, which may be less than or equal to the time metric 310 (if the time metric 310 corresponds to 30 ms). Further, Operation2 and Operation4 may have a combined duration of 30 ms, Operation3 and Operation4 may have a combined duration of 15 ms, and Operation3 and Operation5 may have a combined duration of 30 ms, each of which may be less than or equal to the time metric 310 (if the time metric 310 corresponds to 30 ms). Accordingly, in some examples, the dynamic self-test scheduler 164 may determine that the combination of Operation2 and Operation3, the combination of Operation2 and Operation4, the combination of Operation3 and Operation4, and the combination of Operation3 and Operation5 each satisfy the time metric 310 (and are eligible to be performed during the idle period 354).

Alternatively, or in addition, the one or more criteria 308 may include a power metric 312 for the self-test 350. To illustrate, in some examples, the dynamic self-test scheduler 164 may receive power information 370 indicating a power usage 374 (e.g., an amount of power used, or allocated to be used, by the SoC 100 during a particular time interval). In some examples, the PMIC 168 of FIG. 1 may determine the power usage 374 and may provide the power information 370 to the dynamic self-test scheduler 164. As referred to herein, “power” may indicate a rate energy is used, an amount of energy used, or both. In the example of FIG. 3, the power metric 312 may correspond to 90 (e.g., 90 amps (A), 90 milliamps (mA), 90 microamps (uA), 90 watts (W), 90 milliwatts (mW), 90 millijoules (mJ), or 90 joules (J), as illustrative examples).

In some implementations, the dynamic self-test scheduler 164 may determine the power metric 312 based on the power usage 374, such as by subtracting the power usage 374 from a total (or “maximum”) power usage associated with the SoC 100 to determine the power metric 312. Further, the dynamic self-test scheduler 164 may select the one or more operations 352 from among the operations 336 based on a determination that a power usage associated with the one or more operations 352 is less than or equal to the power metric 312.

To further illustrate, in the example of FIG. 3, Operation2 and Operation3 may have a combined power usage of 90 which may be less than or equal to the power metric 312 (if the power metric 312 corresponds to 90). Further, Operation2 and Operation4 may have a combined power usage of 110, which may be greater than the power metric 312 (if the power metric 312 corresponds to 90). Operation3 and Operation4 may have a combined power usage of 90, and Operation 3 and Operation 5 may have a combined power usage of 40, each of which may be less than or equal to the power metric 312 (if the power metric 312 corresponds to 90). Accordingly, in some examples, the dynamic self-test scheduler 164 may determine that the combination of Operation2 and Operation3, the combination of Operation3 and Operation4, and the combination of Operation3 and Operation5 each satisfy the power metric 312 (and are eligible to be performed during the idle period 354). Further, the dynamic self-test scheduler 164 may determine that the combination of Operation2 and Operation4 fails to satisfy the power metric 312 (and are ineligible to be performed during the idle period 354).

Accordingly, the dynamic self-test scheduler 164 may determine one or more of sets of candidate operations that satisfy the one or more criteria 308. In the example of FIG. 3, the one or more sets may include a first set of candidate operations (e.g., Operation2 and Operation3), a second set of candidate operations (e.g., Operation3 and Operation4), and a third set of candidate operations (e.g., Operation3 and Operation5). In some aspects, after determining the one or more sets, the dynamic self-test scheduler 164 may use ages associated with the one or more sets (e.g., as a “tie-breaker”). The ages may include a first age associated with the first set, a second age associated with the second set, and a third age associated with the third set. In the example of FIG. 3, the first age may correspond to three, the second age may correspond to 5, and the third age may correspond to 6.

After determining the one or more sets, the dynamic self-test scheduler 164 may select one of the sets (e.g., the first set, the second set, or the third set) as the one or more operations 352 based on a comparison of ages (e.g., by comparing the first age, the second age, and the third age). In the example of FIG. 3, the ages may indicate that the Operation2 and Operation3 are less recently used than Operation3 and Operation4 and are also less recently used than Operation3 and Operation5. For example, the combination of Operation2 and Operation3 may be associated with a lower age (3) as compared to the combination of Operation3 and Operation4 (5) and as compared to the combination of Operation3 and Operation5 (6). In this example, the dynamic self-test scheduler 164 may select Operation2 and Operation3 as the one or more operations 352.

In some circumstances, the dynamic self-test scheduler 164 may determine that no candidate operations satisfy the one or more criteria 308. In some such examples, the dynamic self-test scheduler may decline to initiate any operations of the self-test 350 during the idle period 354 (e.g., by deferring the one or more operations 352 until a subsequent idle period). As an illustrative example, if no candidate operations satisfy the one or more criteria 308 during the first idle period (Idle1), the dynamic self-test scheduler may defer the one or more operations 352 until a subsequent idle period, such as the second idle period (Idle2) or the third idle period (Idle3), when the one or more operations 352 satisfy the one or more criteria 308. In some such examples, the idle period 354 may correspond to the second idle period (Idle2) or the third idle period (Idle3). Alternatively, or in addition, the dynamic self-test scheduler 164 may iteratively decrease a quantity of candidate operations for the self-test 350, such as by first evaluating sets of three candidate operations, then evaluating sets of two candidate operations if no set of three candidate operations satisfies the one or more criteria 308, and then evaluating each candidate operation individually if no set of two candidate operations satisfies the one or more criteria 308.

The dynamic self-test scheduler 164 may initiate the one or more operations 352 at the SoC 100. In some examples, one or more interrupts 364 may be provided to one or more applications 360 executed by the SoC 100 (e.g., where the one or more applications 360 are executed by one or more of the CPU 104, the DSP 112, the NPU 124, or the GPU 126). Further, in some examples, the one or more applications 360 may issue one or more power-on reset (POR) commands 368 based on the one or more interrupts 364 or based on completion of the self-test 350 (e.g., to initiate a POR of one or more of the CPU 104, the DSP 112, the NPU 124, or the GPU 126). In some examples, the POR may be performed following the self-test 350 to place one or more components in a functional mode following the self-test 350.

After initiation of the one or more operations 352 by the dynamic self-test scheduler 164 (e.g., by outputting a self-test command that indicates the SoC 100 of FIGS. 1 and 2 is initiate the self-test 350), one or more components of the SoC 100 may perform the one or more operations 352 of the self-test 350. Performing the one or more operations 352 of the self-test 350 may include generating test results. In some examples, the self-test controller 162 of FIG. 1 may receive the test results. If the test results indicate one or more potential faults or failures, the self-test controller 162 may perform one or more actions, such as initiating a reboot of a component or providing an interrupt to the component (e.g., to reset the component), as illustrative examples. In some other examples, if the test results indicate no potential faults or failures, the self-test controller 162 may decline to perform such actions.

In some examples, an idle period may include or may refer to a time period associated with a quantity of executed instructions, or a quantity of tasks, that fails to satisfy (e.g., is less than, or is less than or equal to) a threshold. For example, FIG. 3 illustrates that the first task (Task1) may be performed during an active period, and the first idle period (Idle1) may correspond to an idle period. In such examples, the threshold may correspond to one task. Other examples are also within the scope of the disclosure, such as where the threshold may correspond to another quantity of tasks, or to a quantity of executed instructions. Further, in some examples, an active period may be referred to as a first time period, and an idle period may be referred to as a second time period. The first time period may be associated with a first quantity of one or more tasks that satisfies the threshold, and the second time period may be associated with a second quantity of one or more tasks that fails to satisfy the threshold.

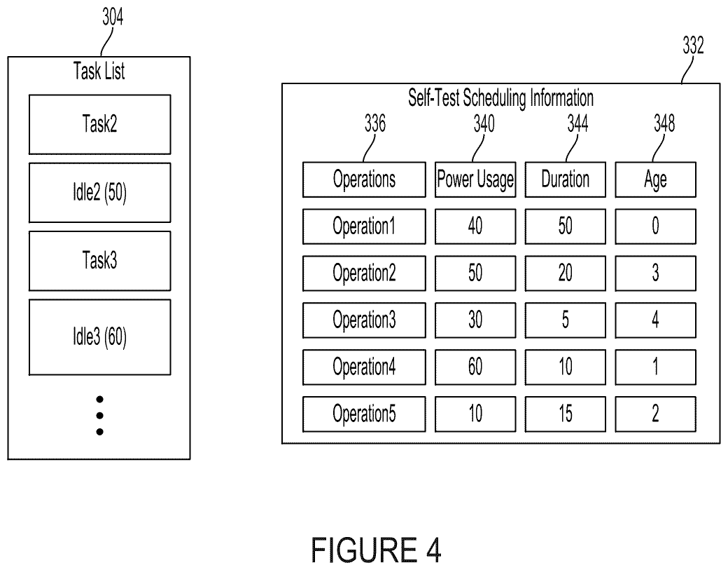

FIG. 4 is a block diagram illustrating additional examples of features that may be associated with the dynamic self-test scheduler 164 supporting dynamic selection of operations for a self-test. In the example of FIG. 4, Operation2 and Operation3 may have been executed during the idle period 354 as the one or more operations 352. Accordingly, the age 348 associated with Operation2 and Operation3 may be adjusted to from 1 and 2 to 3 and 4, respectively.

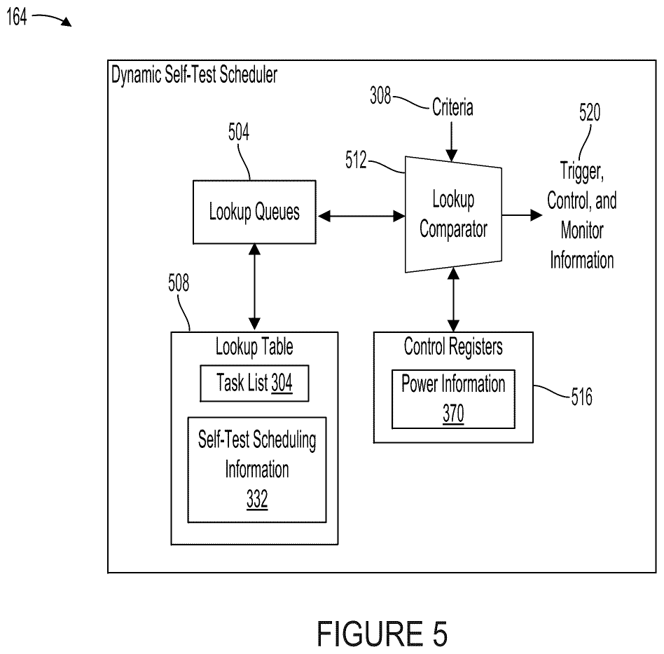

FIG. 5 is a block diagram illustrating additional examples of features that may be associated with the dynamic self-test scheduler 164 supporting dynamic selection of operations for a self-test. In the example of FIG. 5, the dynamic self-test scheduler 164 may include lookup queues 504 and a lookup comparator 512 coupled to the lookup queues 504. The dynamic self-test scheduler 164 may also include, or may store, a lookup table 508 that is accessible to the lookup queues 504. The dynamic self-test scheduler 164 may further include control registers 516 coupled to the lookup comparator 512.

During operation, the lookup queues 504 may access control information stored by the lookup table 508. For example, in some implementations, the lookup queues 504 may store the task list 304, and the lookup queues 504 may receive information of the task list 304 from the lookup queues 504. Alternatively, or in addition, the lookup queues 504 may store the self-test scheduling information 332, and the lookup queues 504 may receive the self-test scheduling information 332 from the lookup queues 504. The lookup queues 504 may queue information retrieved from the lookup table 508.

The lookup comparator 512 may receive information from the control registers 516. In some examples, the lookup comparator 512 may receive the power information 370 from the control registers 516. The lookup comparator 512 may perform one or more comparison operations to determine whether data input to the comparator indicates whether one or more operations 352 indicated by the self-test scheduling information 332 satisfy the one or more criteria 308. Based on determining that one or more operations 352 satisfy the one or more criteria 308, the lookup comparator 512 may output an indication (e.g., trigger, control, and monitor information 520) that the one or more operations 352 are to be performed during an idle period, such as the idle period 354.

To further illustrate, in some examples, the lookup table 508 may include one or more register files storing power and time numbers of LBIST patterns per core per seed. The lookup queues 504 may queue trigger events for the self-test 350. The control registers 516 may store one or more of functional isolation controls, analog safe starting controls, logic retention controls, or other controls. The lookup comparator 512 may generate staggered sequences of trigger events associated with the self-test 350. The trigger, control, and monitor information 520 may be used to override a log to trigger signals of a control unit (such as a BIST control unit) and to monitor status associated with the self-test 350.

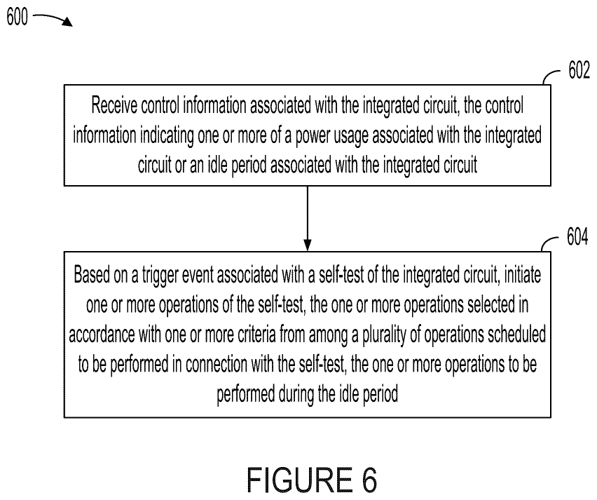

FIG. 6 is a flow chart illustrating an example of a method 600 that supports dynamic selection of operations for a self-test. In some examples, one or more operations of the method 600 may be initiated, performed, or controlled by the self-test controller 162, such as by the one or more processors 222. In some examples, the self-test described with reference to the method 600 may correspond to the self-test 350.

The method 600 includes receiving control information associated with the integrated circuit, at 602. The control information indicates one or more of a power usage associated with the integrated circuit or an idle period associated with the integrated circuit. For example, the dynamic self-test scheduler 164 may receive one or more of an indication of the power usage 374 associated with the SoC 100 or an indication of idle period associated with the SoC 100, such as the idle period 354. In such examples, the control information may indicate one or more of the power usage 374 or the idle period 354.

The method 600 further includes initiating, based on a trigger event associated with a self-test of the integrated circuit, one or more operations of the self-test, at 604. The one or more operations are selected in accordance with one or more criteria from among a plurality of operations scheduled to be performed in connection with the self-test. The one or more operations are to be performed during the idle period. For example, the dynamic self-test scheduler 164 may initiate the one or more operations 352 of the self-test 350 based on the trigger event 306. The dynamic self-test scheduler 164 may select the one or more operations 352 in accordance with the one or more criteria 308. The plurality of operations may include, for example, the operations 336, one or more other operations, or a combination thereof. The one or more operations may be performed during the idle period 354.

By dynamically selecting the one or more operations 352 for the self-test 350 based on one or more of the time metric 310 or the power metric 312, operation of an integrated circuit (e.g., the SoC 100) may be improved as compared to some other testing techniques. To illustrate, some conventional testing techniques may involve periodically performing operations based on a least-recently used (LRU) technique irrespectively of one or more of a power consumption associated with the operations or a time duration associated with the operations. As a result, in some conventional techniques, a test may cause a power reduction event (e.g., where an amount of power available is insufficient to perform one or more operations due to power consumption associated with the test), a stall condition (e.g., where a processor is unable to execute instructions, access a memory, or perform other operations due to resources being utilized in connection with the test), or a malfunction in case of the power consumption exceeding a power budget. Accordingly, by dynamically selecting the one or more operations 352 for the self-test 350 based on one or more of the time metric 310 or the power metric 312, operation may be improved (e.g., by avoiding one or more of a power reduction event or a stall condition at an integrated circuit, such as the SoC 100).

To further illustrate some aspects, in a first aspect, an apparatus for a self-test of an integrated circuit includes a processing system including one or more processors and one or more memories coupled to the one or more processors. The processing system is configured to receive control information associated with the integrated circuit. The control information indicates one or more of a power usage associated with the integrated circuit or an idle period associated with the integrated circuit. The processing system is further configured to initiate, based on a trigger event associated with the self-test of the integrated circuit, one or more operations of the self-test. The one or more operations are selected in accordance with one or more criteria from among a plurality of operations scheduled to be performed in connection with the self-test. The one or more operations are to be performed during the idle period.

In a second aspect, in combination with the first aspect, the one or more criteria include the power usage being less than or equal to a power metric for the self-test, and the power metric is based on the power usage.

In a third aspect, in combination with one or more of the first aspect or the second aspect, the one or more criteria include a duration of the one or more operations being less than or equal to a time metric for the self-test, and the time metric based on the idle period.

In a fourth aspect, in combination with one or more of the first aspect through the third aspect, the one or more criteria include each of the power usage being less than or equal to a power metric for the self-test and a duration of the one or more operations being less than or equal to a time metric for the self-test. The power metric is based on the power usage, and the time metric is based on the idle period.

In a fifth aspect, in combination with one or more of the first aspect through the fourth aspect, the processing system is further configured to determine that a first set of candidate operations for the self-test satisfy the one or more criteria, to determine that a second set of candidate operations for the self-test satisfy the one or more criteria, and after determining the first set and the second set, select one of the first set or the second set as the one or more operations based on a comparison of a first age associated with the first set and a second age associated with the second set.

In a sixth aspect, in combination with one or more of the first aspect through the fifth aspect, the processing system is further configured to detect the trigger event based on detection of a bootup of the integrated circuit.

In a seventh aspect, in combination with one or more of the first aspect through the sixth aspect, the processing system is further configured to detect the trigger event based on detection of expiration of a time interval since a prior iteration of the self-test.

In an eighth aspect, a method of operation of a test controller of an integrated circuit includes receiving control information associated with the integrated circuit. The control information indicates one or more of a power usage associated with the integrated circuit or an idle period associated with the integrated circuit. The method further includes initiating, based on a trigger event associated with a self-test of the integrated circuit, one or more operations of the self-test. The one or more operations are selected in accordance with one or more criteria from among a plurality of operations scheduled to be performed in connection with the self-test. The one or more operations are to be performed during the idle period.

In a ninth aspect, in combination with the eighth aspect, the one or more criteria include the power usage being less than or equal to a power metric for the self-test, the power metric based on the power usage.

In a tenth aspect, in combination with one or more of the eighth aspect through the ninth aspect, the one or more criteria include a duration of the one or more operations being less than or equal to a time metric for the self-test, the time metric based on the idle period.

In an eleventh aspect, in combination with one or more of the eighth aspect through the tenth aspect, the one or more criteria include each of the power usage being less than or equal to a power metric for the self-test and a duration of the one or more operations being less than or equal to a time metric for the self-test. The power metric is based on the power usage, and the time metric is based on the idle period.

In a twelfth aspect, in combination with one or more of the eighth aspect through the eleventh aspect, the method further includes determining that a first set of candidate operations for the self-test satisfy the one or more criteria, determining that a second set of candidate operations for the self-test satisfy the one or more criteria, and after determining the first set and the second set, selecting one of the first set or the second set as the one or more operations based on a comparison of a first age associated with the first set and a second age associated with the second set.

In a thirteenth aspect, in combination with one or more of the eighth aspect through the twelfth aspect, detecting the trigger event includes detecting a bootup of the integrated circuit.

In a fourteenth aspect, in combination with one or more of the eighth aspect through the thirteenth aspect, detecting the trigger event includes detecting expiration of a time interval since a prior iteration of the self-test.

In a fifteenth aspect, a non-transitory computer-readable medium stores instructions executable by one or more processors to initiate, perform, or control operations of a self-test of an integrated circuit. The operations include receiving control information associated with the integrated circuit. The control information indicates one or more of a power usage associated with the integrated circuit or an idle period associated with the integrated circuit. The operations further include initiating, based on a trigger event associated with the self-test of the integrated circuit, one or more operations of the self-test. The one or more operations are selected in accordance with one or more criteria from among a plurality of operations scheduled to be performed in connection with the self-test. The one or more operations to be performed during the idle period.

In a sixteenth aspect, in combination with the fifteenth aspect, the one or more criteria include the power usage being less than or equal to a power metric for the self-test, the power metric based on the power usage.

In a seventeenth aspect, in combination with one or more of the fifteenth aspect through the sixteenth aspect, the one or more criteria include a duration of the one or more operations being less than or equal to a time metric for the self-test, the time metric based on the idle period.

In an eighteenth aspect, in combination with one or more of the fifteenth aspect through the seventeenth aspect, the one or more criteria include each of the power usage being less than or equal to a power metric for the self-test, the power metric based on the power usage, and a duration of the one or more operations being less than or equal to a time metric for the self-test, the time metric based on the idle period.

In a nineteenth aspect, in combination with one or more of the fifteenth aspect through the eighteenth aspect, the operations further include determining that a first set of candidate operations for the self-test satisfy the one or more criteria, determining that a second set of candidate operations for the self-test satisfy the one or more criteria, and after determining the first set and the second set, selecting one of the first set or the second set as the one or more operations based on a comparison of a first age associated with the first set and a second age associated with the second set.

In a twentieth aspect, in combination with one or more of the fifteenth aspect through the nineteenth aspect, detecting the trigger event includes one or more of detecting a bootup of the integrated circuit or detecting expiration of a time interval since a prior iteration of the self-test.

As used herein, the term “processing core” or “BIST core” may refer to a unit within a processing unit (e.g., a CPU or a GPU) that performs computation and processes instructions where each core may independently execute tasks by reading and executing program instructions. Each processing core may all have access to a memory, such as a cache, which may store data. As used herein, the term “cluster,” “a set of processing cores,” or “a subset of processing cores,” may refer to a group of processing cores that share some resources, such as cache memory or power management features. The clusters may communicate with each other, via a high-speed interconnect or bus, to share data across the entire CPU, which may enable coordinated multitasking. A particular processing core or a set of processing cores may be “functional,” which may be operational and fully capable of executing instructions, handling tasks, and performing computations. A particular processing core or a set of processing cores may be “non-functional,” which may be disabled, faulty, in a standby mode, or otherwise unable to execute certain instructions. In some aspects, a device may fuse or completely turn off non-functional cores or underperforming cores. As used herein, the term “bypass” may refer to skipping BIST when other cores are subject to BIST.

As used herein, the term “built-in self-test (BIST)” may refer to a scheme that enables a component, such as a CPU or a GPU, to test itself automatically without external testing equipment. BIST may generate test patterns or stimuli and then apply these to various parts of the component (e.g., logic gates, memory cells, interconnections) to check for issues, such as non-functional processing cores. In some aspects, a BIST may involve multi-phase tests.

In the figures, a single block may be described as performing a function or functions. The function or functions performed by that block may be performed in a single component or across multiple components, and/or may be performed using hardware, software, or a combination of hardware and software. To illustrate, various illustrative components, blocks, modules, circuits, and operations may be described in terms of functionality. Whether such functionality is implemented as hardware or software may depend upon the particular application and the overall system design. Skilled artisans may implement the described functionality in varying ways for each particular application, but such implementation decisions should not be interpreted as causing a departure from the scope of the disclosure. Also, the example devices may include components other than those shown, including well-known components such as a processor, memory, and the like.

As used herein, the term “determine” or “determining” encompasses a wide variety of actions and, therefore, “determining” can include sensing, calculating, computing, processing, deriving, estimating, investigating, looking up (such as via looking up in a table, a database, or another data structure), inferring, ascertaining, or measuring, among other possibilities. Also, “determining” can include receiving (such as receiving information), accessing (such as accessing data stored in memory) or transmitting (such as transmitting information), among other possibilities. Additionally, “determining” can include resolving, selecting, obtaining, choosing, establishing and other such similar actions.

The terms “device” and “apparatus” are not limited to one or a specific number of physical objects (such as one smartphone, one camera controller, one processing system, and so on). As used herein, a device may be any electronic device with one or more parts that may implement at least some portions of the disclosure. While the description and examples herein use the term “device” to describe various aspects of the disclosure, the term “device” is not limited to a specific configuration, type, or number of objects. As used herein, an apparatus may include a device or a portion of the device for performing the described operations.

Certain components in a device or apparatus described as “means for accessing,” “means for receiving,” “means for sending,” “means for using,” “means for selecting,” “means for determining,” “means for normalizing,” “means for multiplying,” or other similarly-named terms referring to one or more operations on data, such as image data, may refer to processing circuitry (such as one or more of an application specific integrated circuit (ASIC), a digital signal processor (DSP), a graphics processing unit (GPU), a central processing unit (CPU), a computer vision processor (CVP), a neural processing unit (NPU), or a neural signal processor (NSP)) configured to perform the recited function through hardware, software, or a combination of hardware configured by software.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

One or more components, functional blocks, and modules described herein may include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, and/or functions, among other examples, whether referred to as software, firmware, middleware, microcode, hardware description language or otherwise. In addition, features discussed herein may be implemented via specialized processor circuitry, via executable instructions, or combinations thereof.

In one or more aspects, the operations described may be implemented in hardware, digital electronic circuitry, computer software, firmware, including the structures disclosed in this specification and their structural equivalents thereof, or in any combination thereof. Implementations of the subject matter described in this specification also may be implemented as one or more computer programs, which is one or more modules of computer program instructions, encoded on a computer storage media for execution by, or to control the operation of, data processing apparatus.

The operations of a method or algorithm disclosed herein may be implemented in a processor-executable software module which may reside on a computer-readable medium and commercially made available as a computer program product as software. Computer-readable media includes both computer storage media and communication media including any medium that may be enabled to transfer a computer program from one place to another. A storage media may be any available media that may be accessed by a computer. By way of example, and not limitation, such computer-readable media may include random-access memory (RAM), read-only memory (ROM), electrically erasable programmable read-only memory (EEPROM), CD-ROM or other optical disk storage, magnetic disk storage or other magnetic storage devices, or any other medium that may be used to store desired program code in the form of instructions or data structures and that may be accessed by a computer. Also, any connection may be properly termed a computer-readable medium. Disk and disc, as used herein, includes compact disc (CD), laser disc, optical disc, digital versatile disc (DVD), floppy disk, and Blu-ray disc, where disks usually reproduce data magnetically and discs reproduce data optically with lasers. Combinations of the above should also be included within the scope of computer-readable media.

Various modifications to the implementations described in this disclosure may be readily apparent to those skilled in the art, and the generic principles defined herein may be applied to some other implementations without departing from the spirit or scope of this disclosure. Thus, the claims are not intended to be limited to the implementations shown herein but are to be accorded the widest scope consistent with this disclosure, the principles and the novel features disclosed herein.

Additionally, a person having ordinary skill in the art will readily appreciate, opposing terms such as “upper” and “lower,” or “front” and back,” or “top” and “bottom,” or “forward” and “backward,” or “left” and “right” are sometimes used for ease of describing the figures, and indicate relative positions corresponding to the orientation of the figure on a properly oriented page, and may not reflect the proper orientation of any device as implemented.

Certain features that are described in this specification in the context of separate implementations also may be implemented in combination in a single implementation. Conversely, various features that are described in the context of a single implementation also may be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown, or in sequential order, or that all illustrated operations be performed to achieve desirable results. Further, the drawings may schematically depict one or more example processes in the form of a flow diagram. However, other operations that are not depicted may be incorporated in the example processes that are schematically illustrated. For example, one or more additional operations may be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products. Additionally, some other implementations are within the scope of the following claims. In some cases, the actions recited in the claims may be performed in a different order and still achieve desirable results.

As used herein, including in the claims, the term “or,” when used in a list of two or more items, means that any one of the listed items may be employed by itself, or any combination of two or more of the listed items may be employed. For example, if a composition is described as containing components A, B, or C, the composition may contain A alone; B alone; C alone; A and B in combination; A and C in combination; B and C in combination; or A, B, and C in combination. Also, as used herein, including in the claims, “or” as used in a list of items prefaced by “at least one of” indicates a disjunctive list such that, for example, a list of “at least one of A, B, or C” means A or B or C or AB or AC or BC or ABC (that is A and B and C) or any of these in any combination thereof.

As used herein, “based on” is intended to be interpreted in the inclusive sense, unless otherwise explicitly indicated. For example, “based on” may be used interchangeably with “based at least in part on,” “associated with,” “in association with,” or “in accordance with” unless otherwise explicitly indicated. Specifically, unless a phrase refers to “based on only ‘a,’” or the equivalent in context, whatever it is that is “based on ‘a,’” or “based at least in part on ‘a,’” may be based on “a” alone or based on a combination of “a” and one or more other factors, conditions, or information.

The term “substantially” is defined as largely, but not necessarily wholly, what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 5, 5, or 50 percent.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An apparatus for a self-test of an integrated circuit, the apparatus comprising:
a processing system including one or more processors and one or more memories coupled to the one or more processors, the processing system configured to:
receive control information associated with the integrated circuit, the control information indicating one or more of a power usage associated with the integrated circuit or an idle period associated with the integrated circuit; and
based on a trigger event associated with the self-test of the integrated circuit, initiate one or more operations of the self-test, the one or more operations selected in accordance with one or more criteria from among a plurality of operations scheduled to be performed in connection with the self-test, the one or more operations to be performed during the idle period.

2. The apparatus of claim 1, wherein the one or more criteria include the power usage being less than or equal to a power metric for the self-test, the power metric based on the power usage.

3. The apparatus of claim 1, wherein the one or more criteria include a duration of the one or more operations being less than or equal to a time metric for the self-test, the time metric based on the idle period.

4. The apparatus of claim 1, wherein the one or more criteria include each of:
the power usage associated with the one or more operations being less than or equal to a power metric for the self-test, the power metric based on the power usage; and
a duration of the one or more operations being less than or equal to a time metric for the self-test, the time metric based on the idle period.

5. The apparatus of claim 1, wherein the processing system is further configured to:
determine that a first set of candidate operations for the self-test satisfy the one or more criteria;
determine that a second set of candidate operations for the self-test satisfy the one or more criteria; and
after determining the first set and the second set, select one of the first set or the second set as the one or more operations based on a comparison of a first age associated with the first set and a second age associated with the second set.

6. The apparatus of claim 1, wherein the processing system is further configured to detect the trigger event based on detection of a bootup of the integrated circuit.

7. The apparatus of claim 1, wherein the processing system is further configured to detect the trigger event based on detection of expiration of a time interval since a prior iteration of the self-test.

8. A method of operation of a test controller of an integrated circuit, the method comprising:
receiving control information associated with the integrated circuit, the control information indicating one or more of a power usage associated with the integrated circuit or an idle period associated with the integrated circuit; and
based on a trigger event associated with a self-test of the integrated circuit, initiating one or more operations of the self-test, the one or more operations selected in accordance with one or more criteria from among a plurality of operations scheduled to be performed in connection with the self-test, the one or more operations to be performed during the idle period.

9. The method of claim 8, wherein the one or more criteria include the power usage being less than or equal to a power metric for the self-test, the power metric based on the power usage.

10. The method of claim 8, wherein the one or more criteria include a duration of the one or more operations being less than or equal to a time metric for the self-test, the time metric based on the idle period.

11. The method of claim 8, wherein the one or more criteria include each of:
the power usage being less than or equal to a power metric for the self-test, the power metric based on the power usage; and
a duration of the one or more operations being less than or equal to a time metric for the self-test, the time metric based on the idle period.

12. The method of claim 8, further comprising:
determining that a first set of candidate operations for the self-test satisfy the one or more criteria;
determining that a second set of candidate operations for the self-test satisfy the one or more criteria; and
after determining the first set and the second set, selecting one of the first set or the second set as the one or more operations based on a comparison of a first age associated with the first set and a second age associated with the second set.

13. The method of claim 8, wherein detecting the trigger event includes detecting a bootup of the integrated circuit.

14. The method of claim 8, wherein detecting the trigger event includes detecting expiration of a time interval since a prior iteration of the self-test.

15. A non-transitory computer-readable medium storing instructions executable by one or more processors to initiate, perform, or control operations of a self-test of an integrated circuit, the operations comprising:
receiving control information associated with the integrated circuit, the control information indicating one or more of a power usage associated with the integrated circuit or an idle period associated with the integrated circuit; and
based on a trigger event associated with the self-test of the integrated circuit, initiating one or more operations of the self-test, the one or more operations selected in accordance with one or more criteria from among a plurality of operations scheduled to be performed in connection with the self-test, the one or more operations to be performed during the idle period.

16. The non-transitory computer-readable medium of claim 15, wherein the one or more criteria include the power usage being less than or equal to a power metric for the self-test, the power metric based on the power usage.

17. The non-transitory computer-readable medium of claim 15, wherein the one or more criteria include a duration of the one or more operations being less than or equal to a time metric for the self-test, the time metric based on the idle period.

18. The non-transitory computer-readable medium of claim 15, wherein the one or more criteria include each of:
the power usage being less than or equal to a power metric for the self-test, the power metric based on the power usage; and
a duration of the one or more operations being less than or equal to a time metric for the self-test, the time metric based on the idle period.

19. The non-transitory computer-readable medium of claim 15, wherein the operations further comprise:
determining that a first set of candidate operations for the self-test satisfy the one or more criteria;
determining that a second set of candidate operations for the self-test satisfy the one or more criteria; and
after determining the first set and the second set, selecting one of the first set or the second set as the one or more operations based on a comparison of a first age associated with the first set and a second age associated with the second set.

20. The non-transitory computer-readable medium of claim 15, wherein detecting the trigger event includes one or more of detecting a bootup of the integrated circuit or detecting expiration of a time interval since a prior iteration of the self-test.
